(19) United States
(12) Patent Application Publication
(10) Pub. No.: US 2005/0112957 A1
(43) Pub. Date: May 26, 2005

(54) Partial inter-locking metal contact structure for semiconductor devices and method of manufacture

(75) Inventors: Chih-Chao Yang, Beacon, NY (US); Lawrence A. Clevenger, LaGrangeville, NY (US); Timothy J. Dalton, Ridgefield, CT (US); Louis Lu-Chen Hsu, Fishkill, NY (US); Carl Radens, LaGrangeville, NY (US); Keith Kwong-Hon Wong, Wappingers Falls, NY (US)

Correspondence Address: SCULLY SCOTT MURPHY & PRESSER, PC, 400 GARDEN CITY PLAZA, SUITE 300, GARDEN CITY, NY, 11530, US

(73) Assignee: INTERNATIONAL BUSINESS MACHINES CORPORATION, ARMONK, NY (US)

(21) Appl. No.: 10/723,152

(22) Filed: Nov. 26, 2003

(51) Int. Cl. H01L 23/48

(52) U.S. Cl. 439/758

(57) ABSTRACT

A structure and method of fabricating a “Lego”-like interlocking contact for high wiring density semiconductors is characterized in that the barrier liner formed in the contact via extends only partially upwards into the adjacent wire level. As a consequence, current crowding and related reliability problems associated with conventional prior art interconnect structures is avoided and structural integrity of the contact via (metal stud) structure is enhanced. The novel “crown” shape of the Lego-like interlocking contact structure that is fabricated to extend in an upward direction may be employed for other integrated circuit applications including forming capacitor (e.g., MIMCAP) and heat sink structures due to its increased surface area.

### BACKGROUND OF THE INVENTION

1. Field of the Invention

The present invention relates to semiconductor and integrated circuit structures generally and, particularly to a novel metal contact structure and method that exhibits enhanced mechanical integrity and electromigration resistance in BEOL interconnects comprising the structures.

2. Description of the Prior Art

As millions and millions of devices and circuits are squeezed on a semiconductor chip, the wiring density and the number of metal levels are both increased generation after generation. In order to provide low RC for high signal speed, low-k dielectric and copper lines become necessary. The quality of thin metal wirings and studs formed by a Damascene process is extremely important to ensure yield and reliability. Two major problems encountered in this area today are poor mechanical integrity of deep submicron metal studs, and unsatisfied electro-migration resistance in BEOL interconnects. The problem becomes more severe when porous low-k material is used.

A metal line and via formation according to the prior art is described in U.S. Pat. No. 5,098,860 issued to Chakravorty, et al., Mar. 24, 1992 entitled “Method of fabricating high-density interconnect structures having tantalum/tantalum oxide layers”. This reference describes a interconnect structure 10 as illustrated in FIG. 1 including a top metal line, 16, connected to a bottom metal line, 11, through a metal via, 18, and these metallic interconnects are embedded in a low-k dialectic material, 12. Additionally, these metal interconnects are enclosed with diffusion barriers, including liners 14 and 15 in order to prevent out-diffusion of the metallic atoms into the dielectric material, 12, and include a cap insulator layers 13 and 17.

In another prior art teaching, described in U.S. Pat. No. 6,383,920 by Wang, et al. entitled “Process for Enclosing Via for Improved Reliability in Dual Damascene Interconnects”, a via contact comprising a crown-shaped liner is described. In this reference, which is directed to a dual damascene process, a resulting interconnect structure 20 shown in FIG. 2 includes a crown-shaped liner material 25 including liner portions 25a, 25b that extend up to the surface 26 of the upper metal wire level 16. In this structure, current that flows along the interlevel wire 16 and into the stud must pass through higher resistive liner 25 and suffers a crowding effect. This not only creates reliability concerns, but also slows down the signal propagation speed of the structure.

Moreover, each of the metal and stud formations taught in the prior art as shown in FIG. 1 and FIG. 2 fail to improve stud mechanical strength, nor to enhance electromigration effect. For example, as depicted in the perspective view of a portion of a conventional multi-layer conducting interconnect structure 400 shown in FIG. 4(B), there is provided four metal lines, 41, 43, 45 and 47, and their corresponding contact vias 42, 44 and 46. Metal line 41 and 45 are parallel to each other, but perpendicular to both metal lines 43 and 47. In this layout, contact vias all are aligned perfectly to the underlying metal wires. As shown in FIG. 4(B), the locations in the structure depicted by dotted lines represent that either the contact via metal connects directly with the adjoining metal underlayer, or alternately, the diffusion barrier layer forms the interface between the via and the adjoining metal layer. In this conventional structure 40 shown in FIG. 4(B), locations 48 where the formed liner contacts the metal layer always have weak mechanical strength due to the essential thermal mismatch between metal and dielectrics. This failure may be revealed as broken barrier materials, which will eventually degrade the reliability of the circuits.

As a further example, a FIG. 5(B) depicts a portion of a conventional multi-layer conducting interconnect structure 50, however, in this conventional embodiment, the vias are misaligned to the underneath metal lines. Thus, as shown in FIG. 5(B), vias 52 and 56 are misaligned to the underneath metal lines 51 and 55 respectively as shown in the FIG. 5(B). Like the case in FIG. 4(B), in FIG. 5(B), the locations in the structure depicted by dotted lines represent that either the contact via metal connects directly with the adjoining metal underlayer, or alternately, the diffusion barrier layer forms the interface between the via and the adjoining metal layer. In this conventional structure 50 shown in FIG. 5(B), locations 58 where the formed liner contacts the metal layer always have weakened mechanical strength.

Moreover, as depicted in the cross-sectional view of a conventional conducting interconnect structure 90 in FIG. 9(A), there exists essentially two possible paths of electron migration from a contact via 98 into an adjoining upper level metal line 96: a first path 92 representing the one along the metal and the diffusion barrier interface; and, a second path 91 representing the one inside the bulk metal line 96. Since the electromigration resistance is always higher in path 91 than in path, 92, the resulting electromigration issue is much more considerable in path 92 than in path 91. By forcing electrons flow from the contact 98 to the upper metal line 96 through path 91 and avoiding path 92 the circuit reliability is enhanced significantly.

It would thus be highly desirable to provide a method and structure for improving the mechanical strength of submicron metal studs and enhancing electromigration resistance in high wiring density semiconductor chips.

### SUMMARY OF THE INVENTION

It is an object of the present invention to provide a method and structure for improving the mechanical strength of submicron metal studs in multi-level interconnect high wiring density semiconductor structures.

It is an object of the present invention to provide a method and structure for enhancing electromigration in multi-level interconnect high wiring density semiconductor structures.

In the satisfaction of the above objects, a “Lego”-like inter-locking contact structure and method for fabricating the same is provided for high wiring density semiconductors characterized in that the contact liner formed in the via extends only partially into the adjacent wire level. As a consequence, current crowding and related reliability problems associated with conventional prior art interconnect structures is avoided and structural integrity of the stud structure is enhanced.

A “Lego”-like stud structure with a “crown” of liner extending partially into a next wire level significantly enhances the mechanical strength of metal interconnect. Besides, it also improves the electro-migration resistance of BEOL due to a relatively high liner resistance which forces electrons to go around the fence and then flow down through the stud. In this case, current crowding effect is prevented resulting in less electromigration.

According to an aspect of the invention, there is provided a semiconductor interconnect structure and method of manufacture, the structure comprising first level of metal conductor and second level of metal conductor and one level of insulator material formed therebetween, the structure further comprising a dielectric metal contact via formed at the insulator material level for electrically connecting the first metal and second metal conductors, wherein the metal contact via includes metal liner material surrounding the metal contact via, a portion of said metal liner extending partially into an adjacent metal level of the first and second metal levels, in interlocking relation therewith to enhance mechanical strength of the semiconductor interconnect structure and improve electromigration resistance.

According to another aspect of the invention, there is provided a semiconductor capacitor device and method of manufacture, the device comprising a first layer of conductor material forming a bottom node and a first insulator material layer formed thereon; a plurality of metal contact studs formed on said first layer of conductor material having lined sidewall portions extending upwards above a top surface of said insulator material; a second insulator layer formed on said first insulator material layer and conforming to said upward extending lined sidewall portions and, a second layer of conductor material forming a top node on top said second insulator layer, wherein an area density of said capacitor device is improved.

According to a further aspect of the invention, there is provided a semiconductor heat sink structure and method of manufacture, the heat sink structure comprising: a first layer of heat sink material; a layer of insulator material formed on the first heat sink material layer; a plurality of contact studs extending upwards from the heat sink material layer through the insulator material layer, the contact studs having sidewall portions and filled with heat sink material to improve area density of the heat sink structure.

Advantageously, the novel “crown” shape of the Lego-like liner structure that is fabricated to extend in an upward direction may be employed for other integrated circuit applications including forming capacitor (e.g., MIMCAP) and heat sink structures due to its increased surface area.

### BRIEF DESCRIPTION OF THE DRAWINGS

Further features, aspects and advantages of the structures and methods of the present invention will become better understood with regard to the following description, appended claims, and accompanying drawings where:

FIG. 1 depicts a cross-sectional view of a conventional interconnect structure 10 including a top metal line, 16, connected to a bottom metal line, 11, through a metal via 18;

FIG. 2 depicts a cross-sectional view of a interconnect structure 10 according to the prior art wherein a liner extends up to a surface of the adjoined metal layer;

FIG. 3 is a cross-sectional diagram of a first embodiment of the invention showing the formed contact liner in the via extending only partially into the adjacent wire level 16;

FIGS. 4(A)-4(C) depict various top (FIG. 4(A)) and cross-sectional views (FIGS. 4(B)-4(C)) of an interlevel connect structure according to the prior art (FIG. 4(B)) and the inventive interlevel connect structure having the Lego-like inter-locking contact via structure according to a first embodiment of the invention as shown in FIG. 4(C);

FIGS. 5(A)-5(C) depict various top (FIG. 5(A)) and cross-sectional views (FIGS. 5(B)-5(C)) of an interlevel connect structure according to the prior art (FIG. 5(B)) and the inventive interlevel connect structure having the Lego-like inter-locking contact via structure according to a second embodiment of the invention as shown in FIG. 5(C);

FIG. 6 to FIG. 8 depict variations of Lego-contact structures with FIG. 6 depicting a via formation implementing a dual Damascene process with a perfect alignment; FIG. 7 depicting a via formation with a slight misalignment; and, FIG. 8 depicting a via formation implementing a single Damascene process;

FIGS. 9(A) and 9(B) depict two possible paths of electron migration from a contact via into the upper level metal line according to the prior art in (FIG. 9(A)) and according to the current invention (FIG. 9(B));

FIGS. 10(A)-10(H) depict a process sequence for improving the dislocation-related leakage in strained-layer MOSFETs. fabricating a “lego”-like inter-locking contact structure according to the present invention.

FIGS. 11(A)-11(G) depict a step-by-step fabrication process 99 to form an improved MIMCAP device having increased surface area according to the invention; and,

FIGS. 12(A)-12(E) depict a method 300 for fabricating an improved heat sink structure for improving the heat dissipation from semiconductor packages/chips according to the invention.

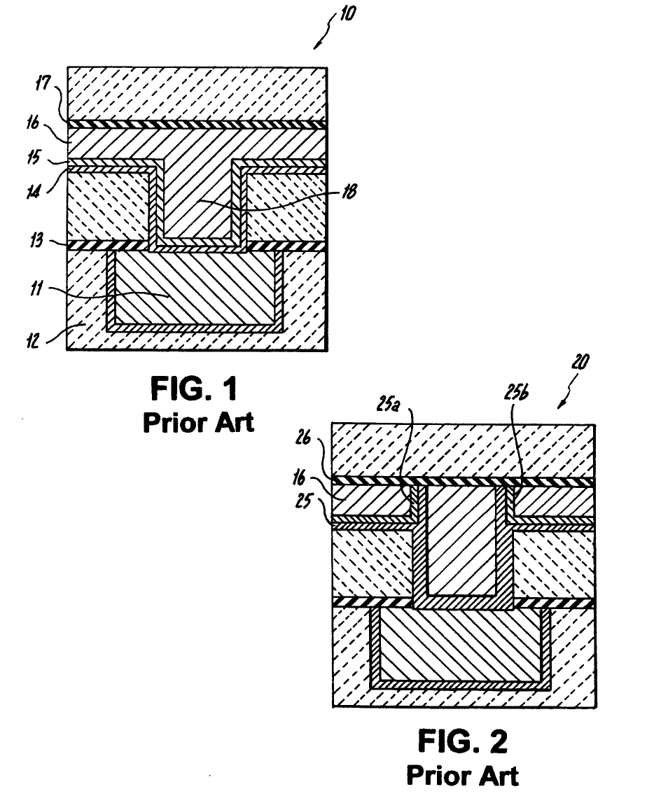

### DETAILED DESCRIPTION OF THE PREFERRED EMBODIMENT

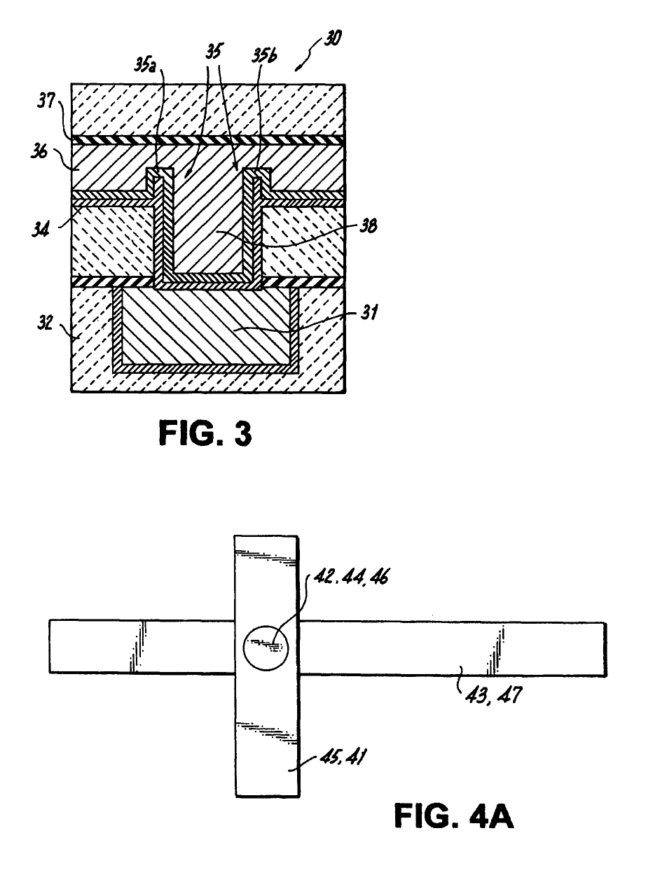

According to the invention, a method of forming new studs having “Lego”-like inter-locking contact structure is proposed. A schematic representation of a cross-sectional interconnect structure 30 according to the current invention is shown in FIG. 3.

As illustrated in FIG. 3, the interconnect structure 30 includes a top metal line, 36 connected to a bottom metal line, 31, through a metal via, 38, and these metallic interconnects are embedded in a low-k dialectic material, 32. Additionally, these metal interconnects are enclosed with diffusion barriers, including a contact liner 34 and 35, and a cap insulator, 37, in order to prevent out-diffusion of the metallic atoms into the dielectric material, 32. However, as shown in FIG. 3, the diffusion barrier portions 35a and 35b formed in the via extends only partially into the adjacent wire level 36.

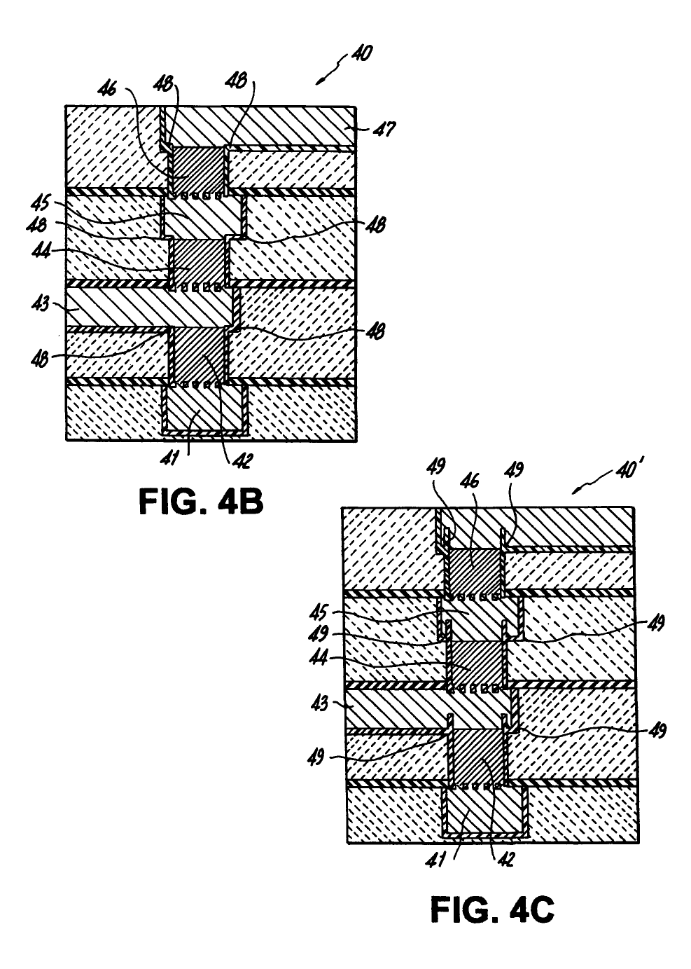

A comparison of the structure and a conventional one is illustrated in FIGS. 4(A)-4(C). In FIG. 4(A) a top view is presented of the prior art interlevel connect structure and the inventive interlevel connect structure 40′ of the invention having the Lego-like inter-locking contact via structure according to the invention as shown in FIG. 4(C).

In both cross-sectional perspective views shown in FIGS. 4(B) and 4(C), there is depicted four metal lines, 41, 43, 45 and 47, and their corresponding contact vias 42, 44 and 46. Metal line 41 and 45 are parallel to each other, but perpendicular to both metal lines 43 and 47. In this layout, contact vias all are aligned perfectly to the underlying metal wires. In the conventional structure 40 shown in FIG. 4(B), sites 48 always have weak mechanical strength due to the essential thermal mismatch between metal and dielectrics. This failure may be revealed as broken barrier materials, which will eventually degrade the reliability of the circuits. However, in the structure 40′ of FIG. 4(C), with a “crown” shape of liner extending only partially upwards into the adjacent conductive layer, the mechanical strength at the locations 49 of FIG. 4(C) in structure 40′ is significantly enhanced.

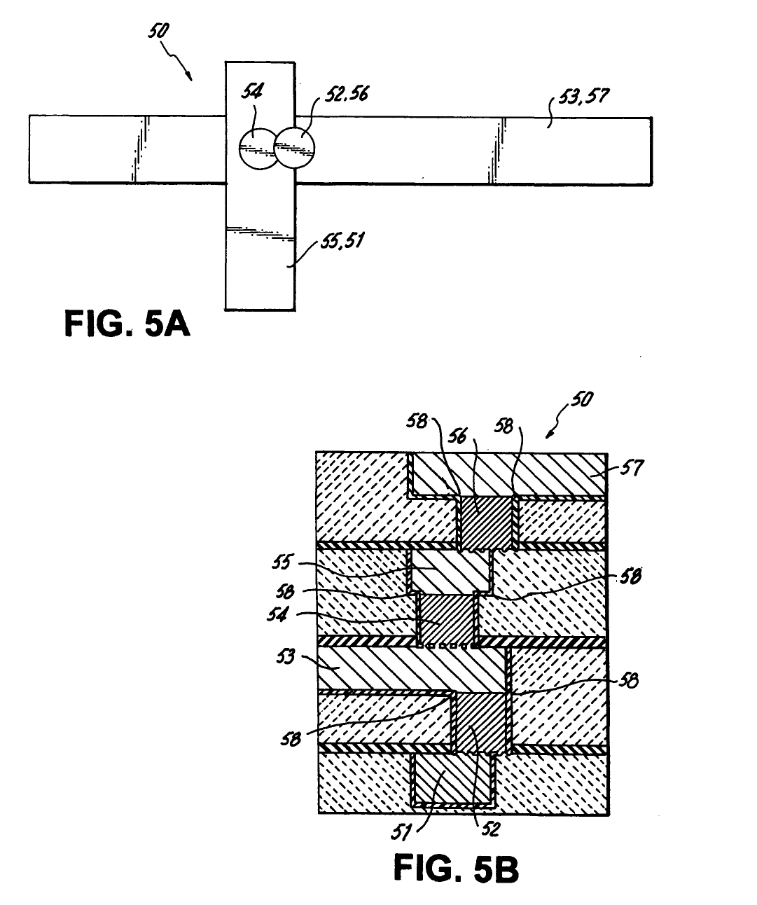

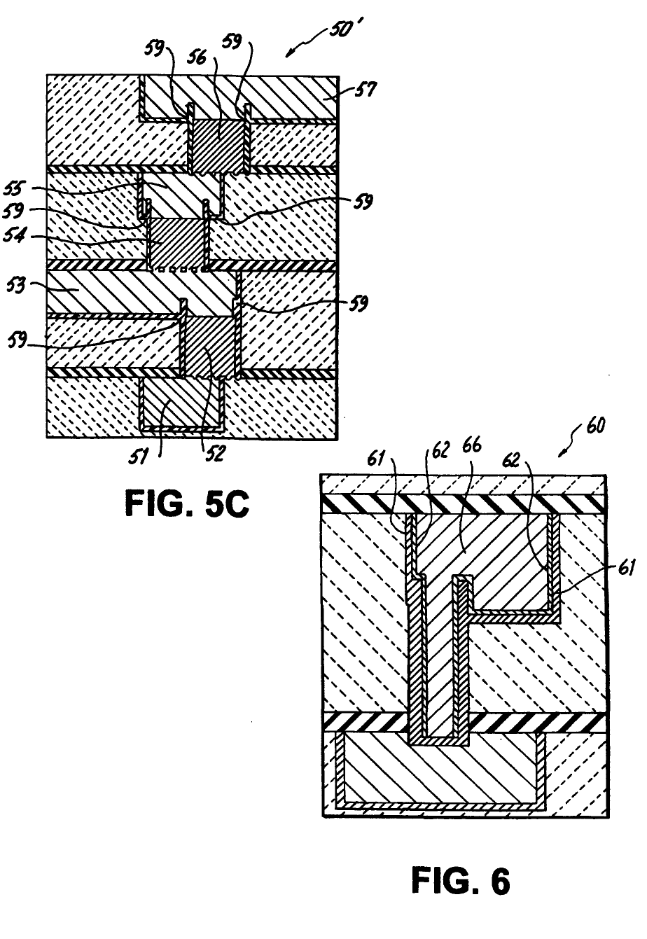

FIGS. 5(A)-5(C) depict similar views as in FIGS. 4(A)-4(C), however, in this case, via 52 and 56 are misaligned to the underneath metal lines, 51 and 55 respectively as shown in the figures. During chip fabrication, this misalignment is observed frequently. FIGS. 5(B)-5(C) are the corresponding cross-sectional representations from a conventional structure 50 (FIG. 5(B) and the structure 50′ FIG. 5(C) of the current invention. Because of the existing “crown” shape of liner extending only partially up into the adjacent conductive layer in the structure 50′, the locations 59 have better mechanical strength than sites 58 as in FIG. 5(A) without the inventive liner shape.

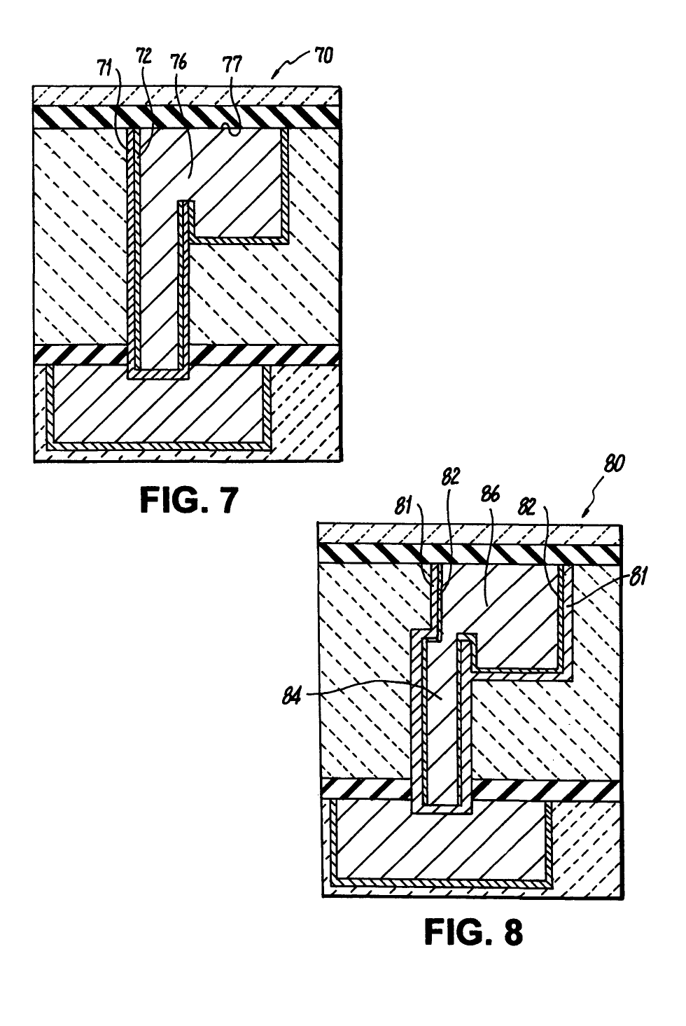

FIG. 6 to FIG. 8 depict variations of Lego-contact structures with FIG. 6 depicting a via formation 60 implementing a dual Damascene process with a perfect alignment; FIG. 7 depicting a via formation 70 with a slight misalignment; and, FIG. 8 depicting a via formation 80 implementing a single Damascene process. In the variation of Lego-contact structure 60 shown in FIG. 6, a dual Damascene process is implemented to result in perfect alignment of liners 61,62 with liner 62 extending partially into the upper metal layer 66. However, in FIG. 7, with a slight misalignment, the liners 71 and 72 extend to the top surface 77 of the metal wire 76. In FIG. 8, the via 84 is formed by using single Damascene process with formed liners 81 and 82 extending partially into the upper metal layer 86 In each structure, the mechanical strength of the interconnects is enhanced. Although, only three structures shown here, it is understood that all other possible combinations of different interconnect structures is contemplated within the scope of the invention.

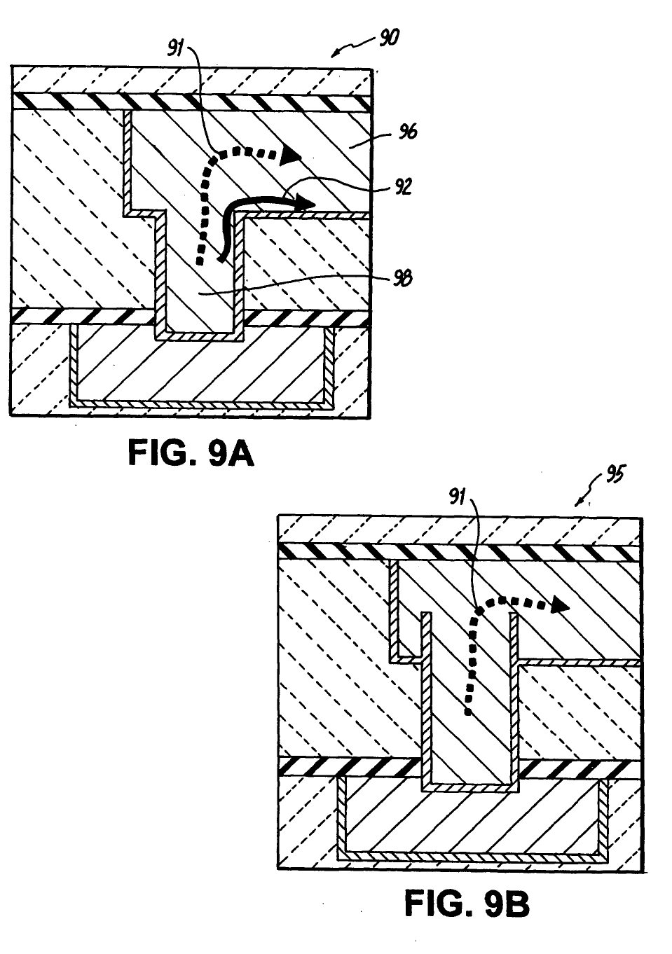

With respect to the electron-migration resistance phenomena, unlike the two possible paths of electron migration from a conventional contact via formation shown in FIG. 9(A), the via formation structure 95 of the invention depicted in FIG. 9(B) has a feature of preventing or slowing down electromigration by forcing electron flow from path 92 (FIG. 9(A)) to path 91.

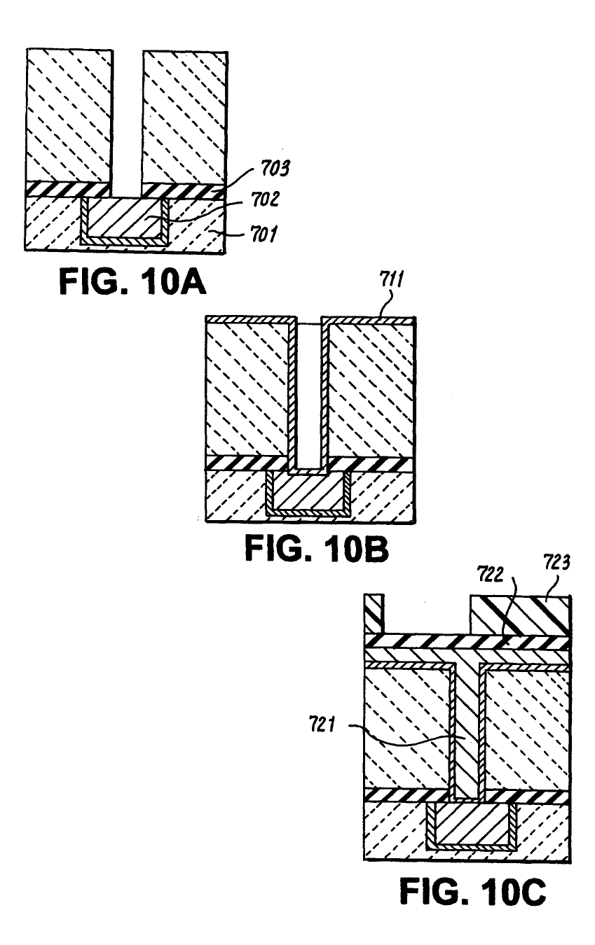

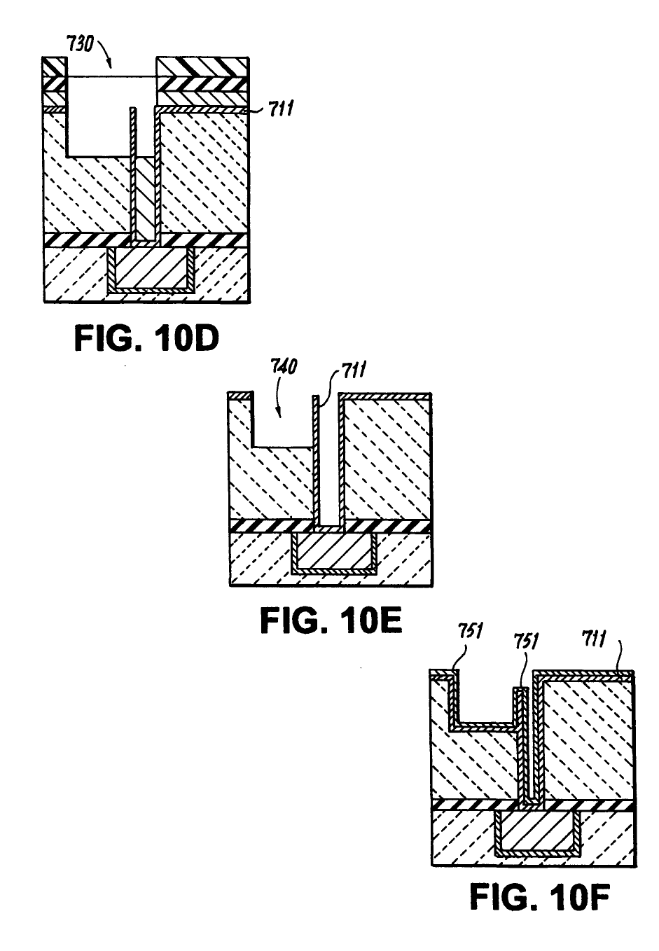

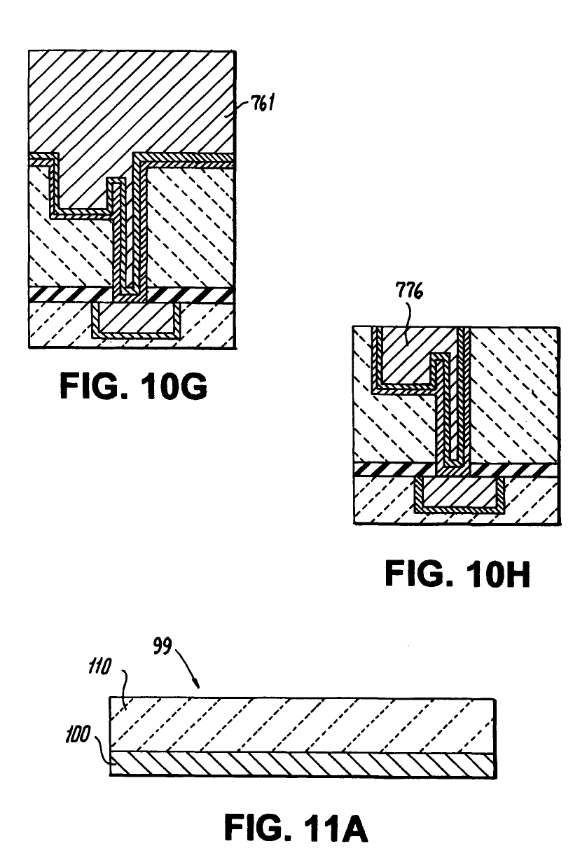

A step-by-step fabrication process 100 to form the interconnect structure of the invention depicted in FIGS. 10(A)-10(G) is now described. A post via etch profile in an insulator such as silicon oxide, silicon nitride, TEOS, or other low-k dielectrics, e.g. SiLK, (Coral, Black Diamond, doped-TEOS, and other organic dielectrics and carbon-doped SiO2 based dielectrics) etc., 701, is shown in FIG. 10(A), wherein the etch opening reaches the underneath metal line 702 through the formed cap layer 703. A diffusion barrier material, 711, is then deposited on the patterned wafer as shown in FIG. 10(B). Preferred diffusion barrier materials may include, but are not limited to: TiN(Si), TaN, Ti, Ta, W, Ru, WN, TaN/Ta and other like materials including combinations thereof. The liner material may be formed in the opening utilizing conventional deposition processes well known to those skilled in the art, including: CVD, PECVD, ALD, PVD, plating and chemical solution deposition. The thickness of the diffusion barrier liner may vary depending upon the liner material as well as the method used in forming the same. Typically, the liner 711 has a thickness from about 5 Å to about 1000 Å and will vary according to the design and process implemented. As shown in FIG. 10(C), a spin-on organic material, 721, and a thin oxide liner layer, 722, are used as planerization layers for metal line patterning, and a photoresist mask 723 is patterned. FIG. 10(D) illustrates the resultant profile 730 after patterning to form top metal layer wiring. The structures 60, 80 depicted in of FIGS. 6 and 8, respectively, will be dependent upon the mask pattern of FIG. 10(D) and the resultant etched profile 730 of FIG. 10(E). The final etching profile 740 is shown in FIG. 10(E) which illustrates the removal of all the resist and filling material 721 utilizing a conventional etch process. A second diffusion barrier, 751, is then deposited as shown in FIG. 10(F) to a thickness of 5 Å˜1000 Å. A layer of conductive material 761 is then filled into the patterned features as shown in FIG. 10(G). Preferred conductive materials may include, but are not limited to the following metals: Cu, Al, W, Ag and alloys thereof. Finally, FIG. 10(G) shows the final profile 776 after removing away extra conductive materials and barrier materials by chemical mechanical polishing (CMP). It is understood that minor variations known to skilled artisans may be implemented to the process such as the employment of further single or dual Damascene processes to result in an interlocking structures as depicted in FIGS. 8 and 6, respectively.

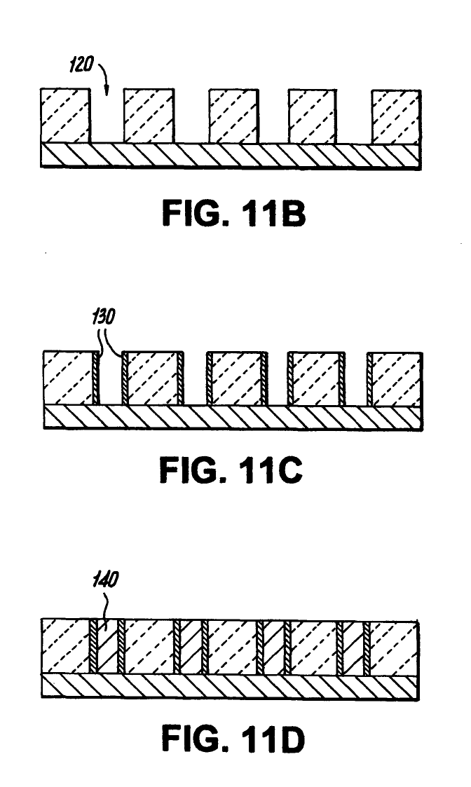

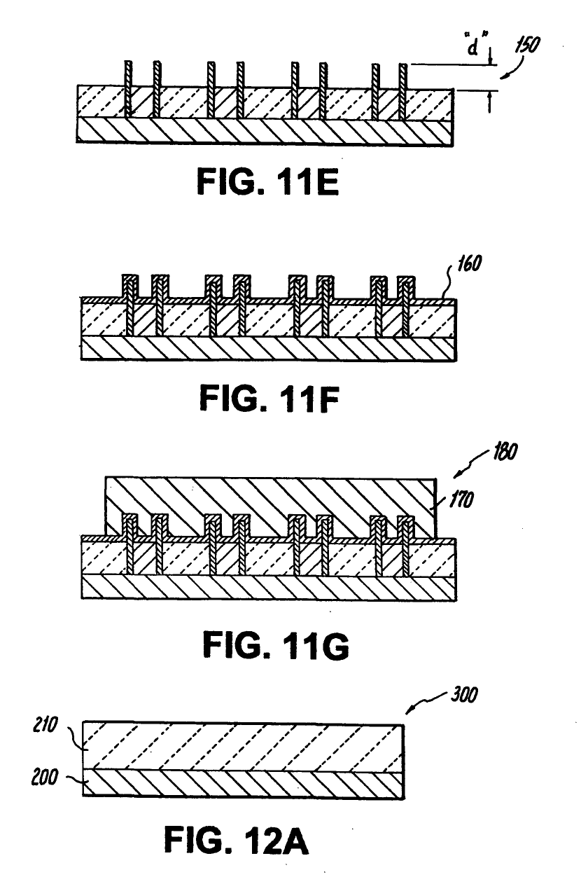

As mentioned, the novel “crown” shape of the Lego-like liner structure that is fabricated to extend from the vias in an upward direction partially into an adjacent conductor level may be employed for other integrated circuit applications including improvement in forming a MIMCAP (metal-insulator-metal capacitor) due to increased surface area. A step-by-step fabrication process 99 to form the MIMCAP having increased surface area according to the invention is depicted in FIGS. 11(A)-11(G).

In a first processing step depicted in FIG. 11(A), a first insulator layer 110, comprising an oxide, nitride, oxynitride of silicon, or equivalent insulator materials, including high-k or low-k dielectric materials which can be sacrificial, is deposited on top of a first patterned metal 100 serving as a bottom plate of the MIMCAP. Utilizing conventional via patterning, an array of vias 120 is formed as depicted in FIG. 11(B). Then, metal liners 130 are formed as depicted in FIG. 11(C) using conventional materials and processes as described herein. Next, the metal studs 140 are formed in the formed vias as depicted in FIG. 11(D) using conventional materials and processes as described herein. Then, the sacrificial insulator 110 is recessed to a predetermined depth “d” 150 as shown in FIG. 11(E). The depth of recess “d” is variable and depends upon the particular application, materials and processing method but may typically range on the order of several angstroms to thousands of angstroms. It is understood that the deeper the recess, the more surface area, but weaker of the free-standing structure. Then, as depicted in FIG. 11(F) using conventional materials and processes, a high-k dielectric material 160 is deposited over the array structure that conforms to extended liners and recesses. Typical high-k dielectric materials that may be used include: TA2O5, (Ba, Sr) TiO3 (BST), SrTiO3 (STO), etc. Finally, a second conductor material, e.g., metal is patterned to form a top plate 170 of the MIMCAP 180 as shown in FIG. 11(G).

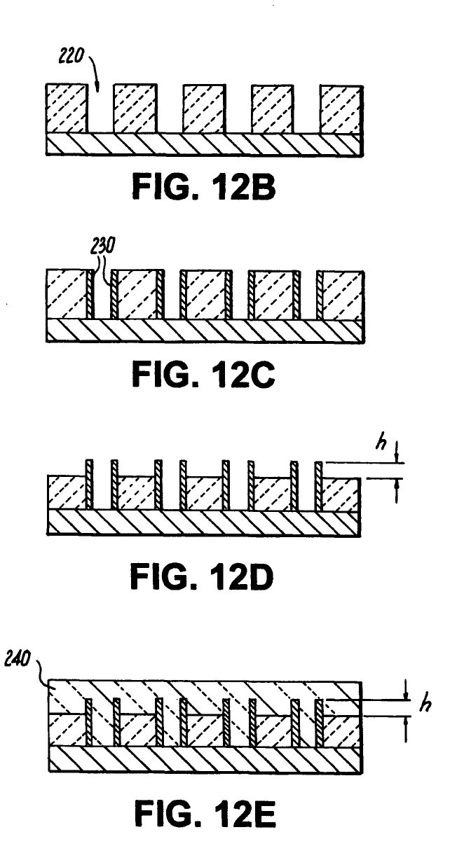

For those semiconductor packages/chips including a heat sink structure, the method for fabricating the novel “crown” shape of the Lego-like structure according to the present invention is advantageous for increasing surface area for heat sink application. Thus, a method 300 to improve heat dissipation from semiconductor packages/chips is now described with respect to FIGS. 12(A)-12(E). With respect to the process for manufacturing an improved heat sink structure, first, as shown in FIG. 12(A), an insulating layer 210 is deposited on a heat sink layer 200. Then, as shown in FIG. 12(B), the insulating layer 210 is patterned to form one or more trenches 220 which are then filled with a conformal coating of heat sink material 230, as shown in FIG. 12(C). Then, in a first embodiment of the heat sink structure, the remaining insulating material of layer 210 is partially removed to a depth, “h”, of several angstroms (Å) to thousands of angstroms as shown in FIG. 12(D) between the conformal coating of heat sink material 230 to improve heat dissipation and retain mechanical strength. In a second embodiment of the improved heat sink structure as shown in FIG. 12(E), the trench openings are filled with a material 240 with desired thermal conductive properties to improve heat removal. It should be understood that the process described with respect to FIGS. 12(A)-12(E) may be generalized to multilevel build sequences.

While the invention has been particularly shown and described with respect to illustrative and preferred embodiments thereof, it will be understood by those skilled in the art that the foregoing and other changes in form and details may be made therein without departing from the spirit and scope of the invention that should be limited only by the scope of the appended claims.

1. A semiconductor interconnect structure comprising first level of metal conductor and second level of metal conductor and one level of insulator material formed therebetween, said structure further comprising a dielectric metal contact via formed at said insulator material level for electrically connecting said first metal and second metal conductors, wherein said metal contact via includes metal liner material surrounding said metal contact via, a portion of said metal liner extending partially into an adjacent metal level of said first and second metal levels, in interlocking relation therewith to enhance mechanical strength of said semiconductor interconnect structure.

2. The semiconductor interconnect structure of claim 1, wherein said adjacent metal level of said first and second metal levels interlocking with said extended portion of said metal liner exhibits increased resistance to electromigration, thereby increasing performance.

3. The semiconductor interconnect structure of claim 1, forming a back-end-of-line interconnect structure exhibiting improved electromigration resistance.

4. The semiconductor interconnect structure of claim 1, wherein said one level of insulator material is a low-k dielectric.

5. The semiconductor interconnect structure of claim 1, further including multiple levels of metal conductors each separated by a level of insulator material formed therebetween, said structure further comprising a metal contact via formed at each said insulator material level for electrically connecting adjacent metal conductor levels, wherein said metal contact via includes metal liner material surrounding said metal contact via, a portion of said metal liner extending partially into each adjacent metal level of said first and second metal levels, in interlocking relation therewith.

6. The semiconductor interconnect structure of claim 5, wherein each metal contact via formed at each insulator material level are aligned.

7. The semiconductor interconnect structure of claim 5, wherein a metal contact via formed at every other insulator material level are aligned and each metal contact via formed at remaining other insulator material levels are offset from an immediate adjacent layer and are aligned.

8. A method of forming a back-end-of-line semiconductor interconnect structure comprising the steps of:
a) forming a first level of metal conductor enclosed in a diffusion barrier material and embedded in a first insulator material layer;
b) forming an insulator cap layer over said first level of metal conductor embedded in said first insulator material layer;
c) forming a second insulator material layer above said insulator cap layer;
d) forming an opening through said second insulator material layer that reaches said first metal conductor level through said formed cap layer to define a contact via opening;
e) forming a diffusion barrier material liner in said etched contact via opening;
f) forming an opening to define a second metal conductor layer, said opening including a portion of said diffusion barrier liner extending partially therein;
g) forming a layer of diffusion barrier liner material in said formed second metal conductor layer opening and in said contact via for lining said second metal conductor level and lining said contact via; and,
h) filling conductive material in said lined contact via opening and in said lined second metal conductor layer for forming said second level of metal conductor layer, wherein said second level of metal conductor layer includes said partially extended portion of diffusion barrier liner material layers of said contact via to enhance mechanical strength of said back-end-of-line semiconductor interconnect structure.

9. The method of forming a back-end-of-line semiconductor interconnect structure as claimed in claim 8, wherein said step g) includes employing a damascene process for forming said layer of diffusion barrier liner material.

10. The method of forming a back-end-of-line semiconductor interconnect structure as claimed in claim 8, wherein said step g) includes employing a dual damascene process for forming said layer of diffusion barrier liner material.

11. The method of forming a back-end-of-line semiconductor interconnect structure as claimed in claim 8, wherein said step f) of forming an opening to define a second metal conductor layer, includes the steps of:
forming one or more planerization layers of material on top said contact via and second insulator material layer;
patterning a region defining a second metal conductor layer region;
etching said one or more planerization layers and a portion of second insulator material in said defined region to a depth ‘d’ such that a portion of said diffusion barrier liner material of said contact via remains in said etched region, said etching including opening said contact via.

12. The method of forming a back-end-of-line semiconductor interconnect structure as claimed in claim 11, wherein said step e) of forming a diffusion barrier material liner in said etched contact via opening includes forming diffusion barrier material layer on top said second insulator material layer.

13. The method of forming a back-end-of-line semiconductor interconnect structure as claimed in claim 12, wherein said step of forming one or more planarization layers includes filling said contact via with an organic material and forming an organic material layer on top said deposited diffusion barrier liner material; and, depositing a thin insulator layer thereover.

14. The method of forming a back-end-of-line semiconductor interconnect structure as claimed in claim 13, wherein said etching said one or more planerization layers further includes removing said organic material layer, said formed diffusion barrier material layer and, removing said portion of second insulator material.

15. The method of forming a back-end-of-line semiconductor interconnect structure as claimed in claim 8, further including the step h) of removing away extra conductive materials and barrier materials by chemical mechanical polishing (CMP).

16. A semiconductor capacitor device comprising a first layer of conductor material forming a bottom node and a first insulator material layer formed thereon; a plurality of metal contact studs formed on said first layer of conductor material having lined sidewall portions extending upwards above a top surface of said insulator material; a second insulator layer formed on said first insulator material layer and conforming to said upward extending lined sidewall portions and, a second layer of conductor material forming a top node on top said second insulator layer, wherein an area density of said capacitor device is improved.

17. The semiconductor capacitor device as claimed in claim 16, wherein said second insulator layer comprises a high-k dielectric material.

18. A method of forming a semiconductor capacitor device comprising the steps of:
a) providing a patterned first conductor layer forming a bottom plate of said device;
b) forming a first insulator material layer on top of said patterned first conductor layer;
c) forming a plurality of metal contact studs contacting said first conductor layer and having sidewall liner portions extending upward;
d) recessing said first insulator material layer to a predetermined depth
e) forming a second insulator layer over the plurality of metal contact studs that conforms to extended sidewall liner portions and recesses formed as a result of recessing step d); and,
f) providing a patterned second conductor layer forming a top plate of said device, wherein an area density of said capacitor device is improved.

19. The method of forming a semiconductor capacitor device as claimed in claim 18, wherein said step c) of forming a plurality of metal contact studs includes forming a plurality of etched via openings, lining said sidewall portions thereof with diffusion barrier materials, and filling said lined via openings with conductor material, said recessing step d) including recessing said first insulator material layer and said filled material in said lined vias to said predetermined depth to thereby form extended sidewall liner portions.

20. The method of forming a semiconductor capacitor device as claimed in claim 18, wherein said plurality of metal contact studs comprises an array.

21. A semiconductor heat sink structure comprising: a first layer of heat sink material; a layer of insulator material formed on said first heat sink material layer; a plurality of contact studs extending upwards from said heat sink material layer through said insulator material layer, said contact studs having sidewall portions and filled with heat sink material to improve area density of said heat sink structure.

22. The semiconductor heat sink structure as claimed in claim 21, wherein said plurality of contact studs comprises an array.

23. The semiconductor heat sink structure as claimed in claim 21, wherein said layer of insulator material remaining between said formed plurality of contact studs is partially recessed.

24. The method of forming a semiconductor heat sink structure comprising the steps of:
a) providing a patterned heat sink material layer of said structure;
b) forming a first insulator material layer on top of said patterned heat sink material layer;
c) forming a plurality of contact studs contacting said heat sink material layer and having sidewall liner portions extending upward; and,
d) partially recessing said first insulator material layer to a predetermined depth in between said formed contact studs, wherein an area density of said heat sink is increased.

25. The method of forming a semiconductor heat sink structure as claimed in claim 24, further comprising the step of: filling in the partially recessed openings in said first insulator material layer with material having suitable thermal conductive properties.
